(19) United States
(12) Patent Application Publication
(10) Pub. No.: US 2008/0023738 A1
(43) Pub. Date: Jan. 31, 2008

(54) Silicon microlens array

(75) Inventor: Victor Lenchenkov, Boise, ID (US)

Correspondence Address: DICKSTEIN SHAPIRO LLP, 1825 EYE STREET, NW, WASHINGTON, DC, 20006, US

(73) Assignee: MICRON TECHNOLOGY, INC.

(21) Appl. No.: 11/494,688

(22) Filed: Jul. 28, 2006

(51) Int. Cl. H01L 31/062

(52) U.S. Cl. 257/294

(57) ABSTRACT

A silicon microlens and method of forming the microlens for focusing and steering light into the photosensitive region of a pixel. The microlens may be formed integrally within a silicon substrate or within a silicon layer over the substrate by performing a series of concentric etches of decreasing depth to produce a generally convex surface on the silicon substrate over the photosensitive region. A dielectric layer having an index of refraction of approximately half that of the silicon material is formed over the silicon microlens. The microlens may also be formed over the substrate by performing the etches over a polysilicon layer formed over the substrate.

### FIELD OF THE INVENTION

The invention relates to an imager having silicon microlenses and a method of making the same.

### BACKGROUND OF THE INVENTION

Solid state imagers, including charge coupled devices (CCD) and CMOS sensors, have been used in photo imaging applications. A solid state imager includes a focal plane array of pixels, each one of the pixels including either a photogate, photoconductor or a photodiode having a doped region for accumulating photo-generated charge. Microlenses are placed over the imager pixels. A microlens is used to focus light onto the charge accumulation region. A single microlens is typically patterned from microlens material into squares or circles provided respectively over the pixels, with color filter arrays, various metallization layers and inter-layer dielectric layers between the microlens and the pixels themselves. The microlenses are heated during manufacturing to shape and cure them.

Use of microlenses significantly improves the photosensitivity of the imager by collecting light from a large light collecting area and focusing it on a small photosensitive area of the pixel. The ratio of the overall light collecting area to the photosensitive area of the pixel is known as the fill factor of the pixel.

For example, FIG. 1 illustrates a cross-section of a typical CMOS imager pixel 11 on a substrate 10 having a photosensitive region 20. Interlayer dielectric and metallization layers 30 are disposed over the substrate 10 and pixel circuitry 25. It should be noted that although two layers are shown for interlayer dielectric and metallization layers 30, these two layers are merely representative of a plurality of such layers. A tetraethyl orthosilicate, Si(OC₂H₅)₄ (“TEOS”) layer 40 may be provided for providing a planarized surface and a color filter layer 50 may be formed over the interlayer dielectric and metallization layers 30. A microlens 70 is formed over the color filter layer 50.

As the complexity of metallization layers increases, it becomes increasingly difficult to provide a microlens capable of focusing incident light rays onto the photosensitive region 20, as a result of increased metal lines in the metallization layer around which incident light must be directed. In addition, an increased number of metallization and interlayer dielectric layers 30 increases the distance through which incident light must be directed from the surface of the microlens 70 to the photosensitive region 20. Also, it is difficult to correct possible distortions created by multiple regions above the photosensitive area, which results in increased “crosstalk” between adjacent pixels. Crosstalk can result when off-axis light strikes a microlens at an obtuse angle. The off-axis light passes through planarization regions and a color filter, misses the intended photosensitive region, and instead strikes an adjacent photosensitive region.

Therefore, it is desirable to have a microlens that is closer to the photosensitive region for focusing and steering light to the intended photosensitive region, and improving the fill factor of the pixel.

### BRIEF DESCRIPTION OF THE DRAWINGS

Features and advantages of the invention will be more clearly understood from the following detailed description, which is provided with reference to the accompanying drawings in which:

FIG. 1 is a cross-section of a prior art pixel;

FIG. 2 is a cross-section of a pixel in accordance with one embodiment of the invention;

FIG. 3A is a cross-section of the pixel of FIG. 2 at an initial stage of fabrication;

FIG. 3B is a cross-section of the pixel of FIG. 2 at a stage of fabrication subsequent to FIG. 3A;

FIG. 3C is a cross-section of the pixel of FIG. 2 at a stage of fabrication subsequent to FIG. 3B;

FIG. 3D is a cross-section of the pixel of FIG. 2 at a stage of fabrication subsequent to FIG. 3C;

FIG. 3E is a cross-section of the pixel of FIG. 2 at a stage of fabrication subsequent to FIG. 3D;

FIG. 4 is a cross-section of a pixel in accordance with another embodiment of the invention;

FIG. 5A is a cross-section of the pixel of FIG. 4 at an initial stage of fabrication;

FIG. 5B is a cross-section of the pixel of FIG. 4 at a stage of fabrication subsequent to FIG. 5A;

FIG. 5C is a cross-section of the pixel of FIG. 4 at a stage of fabrication subsequent to FIG. 5B;

FIG. 5D is a cross-section of the pixel of FIG. 4 at a stage of fabrication subsequent to FIG. 5C;

FIG. 5E is a cross-section of the pixel of FIG. 4 at a stage of fabrication subsequent to FIG. 5D;

FIG. 6 is a block diagram of an imager employing an array of microlenses constructed in accordance with an embodiment of the invention; and

FIG. 7 is a block diagram of a system, e.g., a digital camera, employing an imager in accordance with an embodiment of the invention.

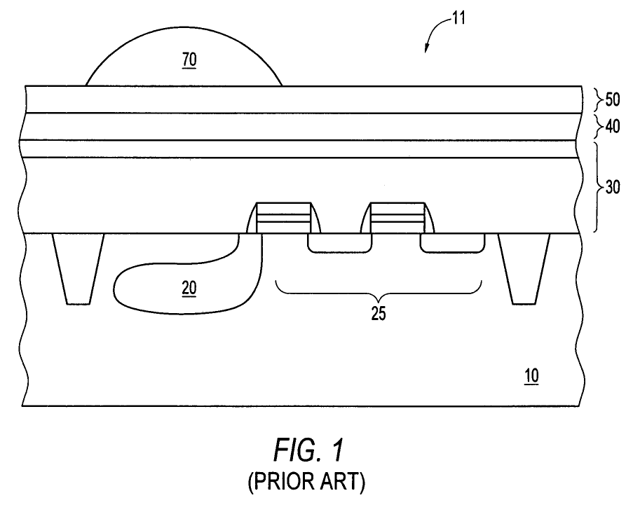

### DETAILED DESCRIPTION OF THE INVENTION

In the following detailed description, reference is made to the accompanying drawings which form a part hereof, and in which is shown by way of illustration specific embodiments in which the invention may be practiced. These embodiments are described in sufficient detail to enable those of ordinary skill in the art to make and use the invention, and it is to be understood that structural, logical, or procedural changes may be made to the specific embodiments disclosed without departing from the spirit and scope of the present invention.

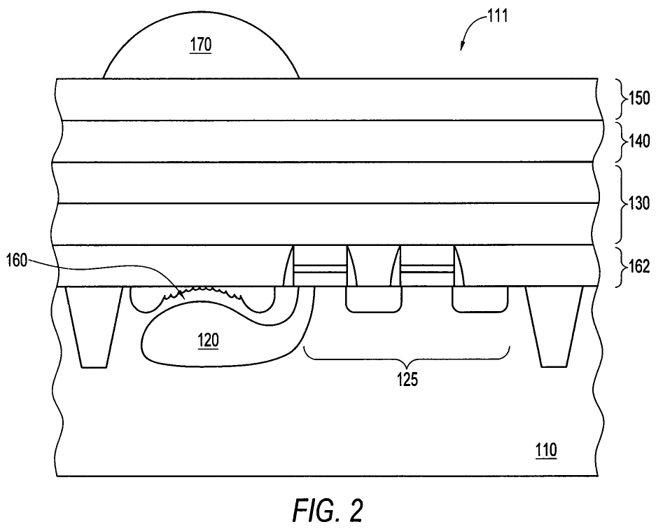

Referring now to the drawings, FIG. 2 illustrates a cross-section of a pixel 111 formed in accordance with one embodiment of the invention. Pixel 111, formed on substrate 110 has a photosensitive region 120. Interlayer dielectric and metallization layers 130 are disposed over the substrate 110 and pixel circuitry 125. It should be noted that although two layers are shown for interlayer dielectric and metallization layers 130, these two layers are merely representative of a plurality of such layers. A TEOS layer 140 for providing a planarized surface and a color filter layer 150 may be formed over the interlayer dielectric and metallization layers 130. A microlens 170 is optionally formed over the color filter layer 150.

A silicon microlens 160 that is located directly over the photosensitive region 120 is also integrally formed within the substrate 110. Microlens 160 is thinner and has a lower radius of curvature than microlens 170. Microlens 160 preferably has a thickness within the range of approximately 0.5μ to approximately 1.0μ and, since it is formed of silicon, has an index of refraction in the range of approximately 3.8 to 5.5. Microlens 160 has a dielectric layer 162 formed over it having an index of refraction that is at least half that of microlens 160, or in the range of approximately 1.5 to 2.0. The dielectric material may be, for example, borophosphosilicate glass (BSPG), which has an index of refraction of approximately 1.47 to 1.49, or nitride anti-reflective coating (nitride ARC or Si₃N₄), which has an index of refraction of approximately 1.93 to 1.99. Alternatively, dielectric layer 162 may comprise a plurality of layers such as the nitride ARC in contact with the silicon microlens 160 and a BPSG layer in contact with the nitride ARC.

Having a high ratio of refraction indices between the silicon microlens 160 and the dielectric layer 162, in this case approximately 2 to 1, directly over the photosensitive region 120 is beneficial for focusing and steering light into the photosensitive region 120, which results in lower crosstalk.

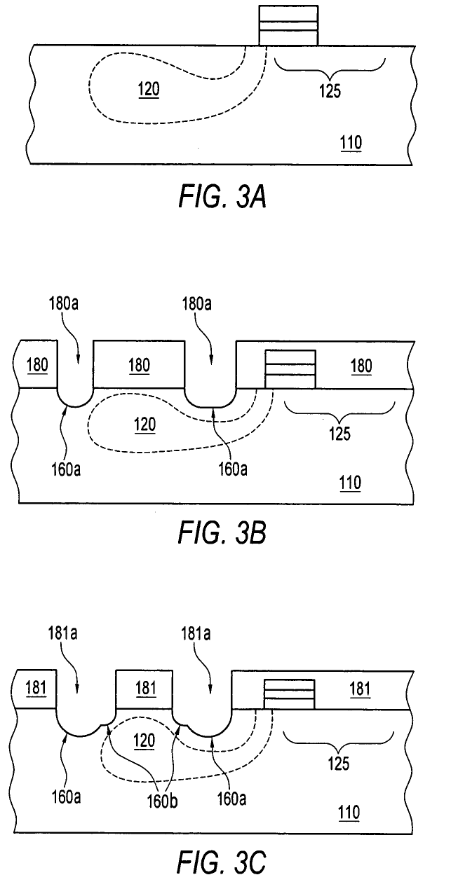

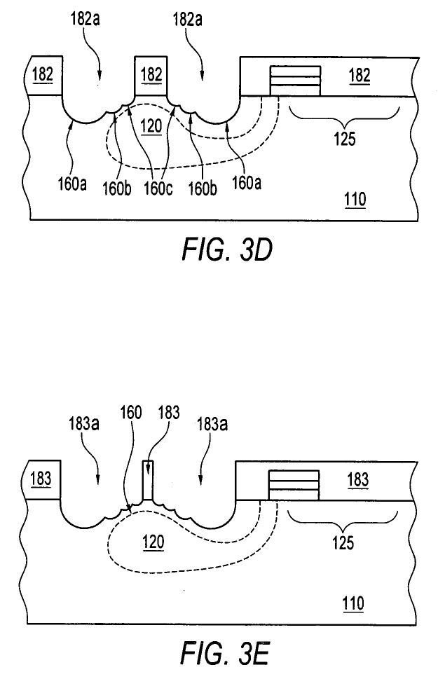

FIGS. 3A-3E illustrate a cross-section of the pixel 111 of FIG. 2 at various stages of fabrication. FIG. 3A illustrates a cross-section of the pixel 111 at an initial stage of fabrication. Substrate 110 has gates and other pixel circuitry 125 formed on it. Photosensitive region 120 is shown in hashed lines to indicate where it will be formed at later stages.

As shown in FIG. 3B, a mask 180 is formed over the substrate 110. Mask 180 has openings 180a around the perimeter of where the photosensitive region 120 will be formed. The silicon substrate 110 is subjected to an etching process to form trenches 160a in the silicon substrate 110.

The process is repeated using masks having progressively larger openings, as shown in FIGS. 3C-3E. As shown in FIG. 3C, mask 181 has openings 181a around the perimeter of where the photosensitive region 120 will be formed. Openings 181a are larger than openings 180a of FIG. 3B while at the same time being concentric in location with the openings 180a of FIG. 3B. The silicon substrate 110 is subjected to another etching process that is shallower than the etch process used in the step shown in FIG. 3B to form trenches 160b in the silicon substrate 110.

As shown in FIG. 3D, mask 182 has openings 182a around the perimeter of where the photosensitive region 120 will be formed. Openings 182a are larger than openings 181a of FIG. 3C while at the same time being concentric in location with the openings 180a, 181a of FIGS. 3B-C, respectively. The silicon substrate 110 is subjected to another etching process that is shallower than the etch process used in the step shown in FIG. 3C to form trenches 160c in the silicon substrate 110.

The process of masking with concentric openings of increasing size and etching to a shallower depth is repeated until a desired contour of microlens 160 is formed with a final mask 183 having openings 183a of the largest size, as shown in FIG. 3E. After etching, the substrate 110 is doped to form the photosensitive region 120 and conventional processing is performed to complete the pixel 111 (FIG.2).

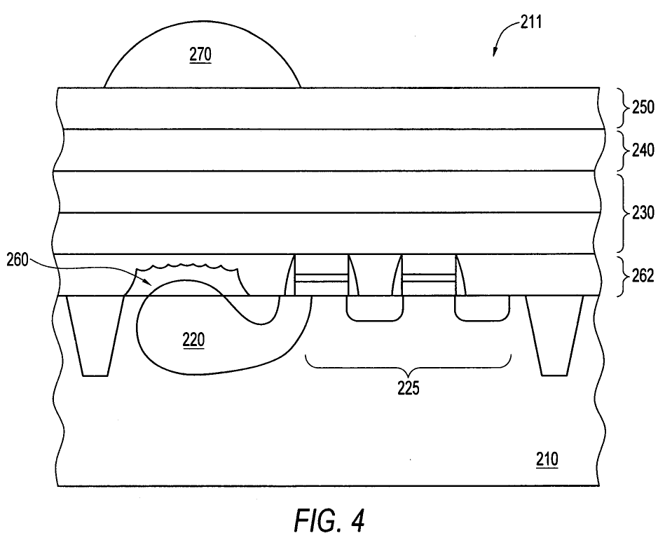

FIG. 4 illustrates a cross-section of a pixel 211 in accordance with another embodiment of the invention. Pixel 211 is formed on a substrate 210 having a photosensitive region 220. Interlayer dielectric and metallization layers 230 are disposed over the substrate 210 and pixel circuitry 225. It should be noted that although two layers are shown for interlayer dielectric and metallization layers 230, these two layers are merely representative of a plurality of such layers. A TEOS layer 240 for providing a planarized surface and a color filter layer 250 may be formed over the interlayer dielectric and metallization layers 230. A microlens 270 is optionally formed over the color filter layer 250.

A silicon microlens 260 that is located directly over the photosensitive region 220 is formed over substrate 210, but below layers 230. The photosensitive region 220 is at least partially within the silicon microlens 260. Microlens 260 is thinner and has a lower radius of curvature than microlens 270. Microlens 260 is formed of crystal silicon or polysilicon material and preferably has an index of refraction in the range of approximately 3.8 to 5.5. The microlens 260 has a dielectric layer 262 formed over it and having an index of refraction that is at least half that of microlens 260, or in the range of approximately 1.5 to 2.0. The dielectric material maybe, for example, borophosphosilicate glass (BSPG), which has an index of refraction of approximately 1.47 to 1.49, or nitride anti-reflective coating (nitride ARC or Si₃N₄), which has an index of refraction of approximately 1.93 to 1.99. Alternatively, dielectric layer 262 may comprise a plurality of layers such as the nitride ARC in contact with the silicon microlens 260 and a BPSG layer in contact with the nitride ARC.

Having a high ratio of refraction indices between the silicon microlens 260 and the dielectric layer 262, in this case approximately 2 to 1, directly over the photosensitive region 220 is beneficial for focusing and steering light onto the photosensitive region 220, which results in lower crosstalk. Furthermore, since polysilicon material is a less transmissive material than silicon, if a polysilicon material is used for the silicon microlens 260, it is preferable to form the photosensitive region 220 at a higher level and at least partially within the polysilicon material, as shown in FIG. 4, in order to maximize the amount of incident light directed to the photosensitive region 220.

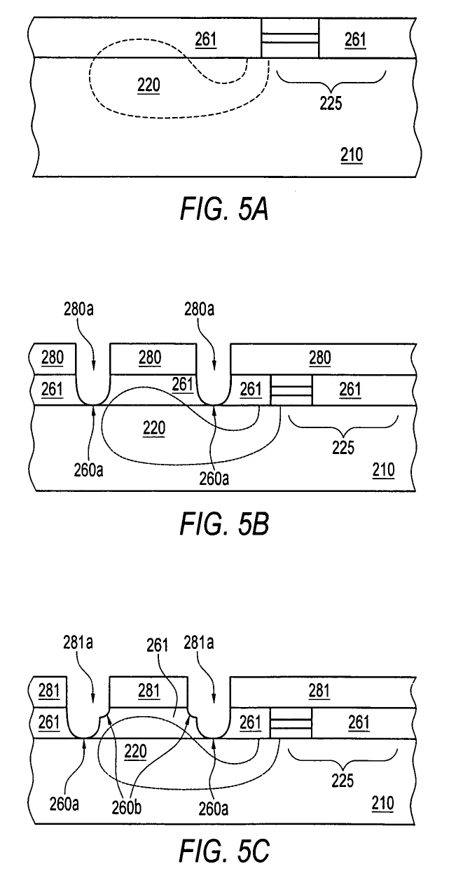

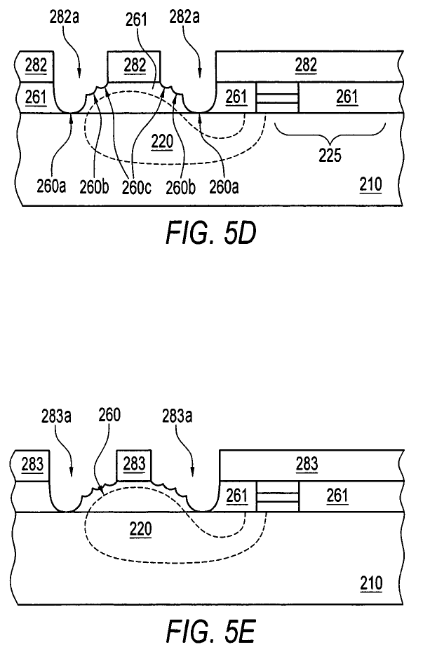

FIGS. 5A-5E illustrate a cross-section of the pixel 211 of FIG. 4 at various stages of fabrication. FIG. 5A illustrates a cross-section of the pixel 211 at an initial stage of fabrication. Substrate 210 has gates and other pixel circuitry 225 formed on it. A silicon layer 261, comprising a silicon material such as polysilicon, is formed over the silicon substrate 210. Photosensitive region 220 is shown in hashed lines to indicate where it will be formed at later stages. As discussed above, since photosensitive region 220 will be at least partially formed within the silicon microlens 260, the photosensitive region 220 protrudes into the silicon layer 261.

As shown in FIG. 5B, a mask 280 is formed over the silicon layer 261. Mask 280 has openings 280a around the perimeter of where the photosensitive region 220 will be formed. The silicon layer 261 is subjected to an etching process to form trenches 260a in the silicon layer 261. Additionally, the etch process may also form trenches that penetrate the silicon substrate 210.

The process is repeated using masks having progressively larger openings, as shown in FIGS. 5C-5E. As shown in FIG. 5C, mask 281 has openings 281a around the perimeter of where the photosensitive region 220 will be formed. Openings 281a are larger than openings 280a of FIG. 5B while at the same time being concentric in location with the openings 280a of FIG. 5B. The silicon layer 261 is subjected to another etching process that is shallower than the etch process used in the step shown in FIG. 5B to form trenches 260b in the silicon layer 261.

As shown in FIG. 5D, mask 282 has openings 282a around the perimeter of where the photosensitive region 220 will be formed. Openings 282a are larger than openings 281a of FIG. 5C while at the same time being concentric in location with the openings 280a, 281a of FIGS. 5B-C, respectively. The silicon layer 261 is subjected to another etching process that is shallower than the etch process used in the step shown in FIG. 5C to form trenches 260c in the silicon layer 261.

The process of masking with concentric openings of increasing size and etching to a shallower depth is repeated until a desired contour of microlens 260 is formed with a final mask 283 having openings 283a of the largest size, as shown in FIG. 5E. After etching, the substrate 210 and silicon microlens 260 are doped to form the photosensitive region 220. Conventional processing is performed to complete the pixel 211 (FIG. 4).

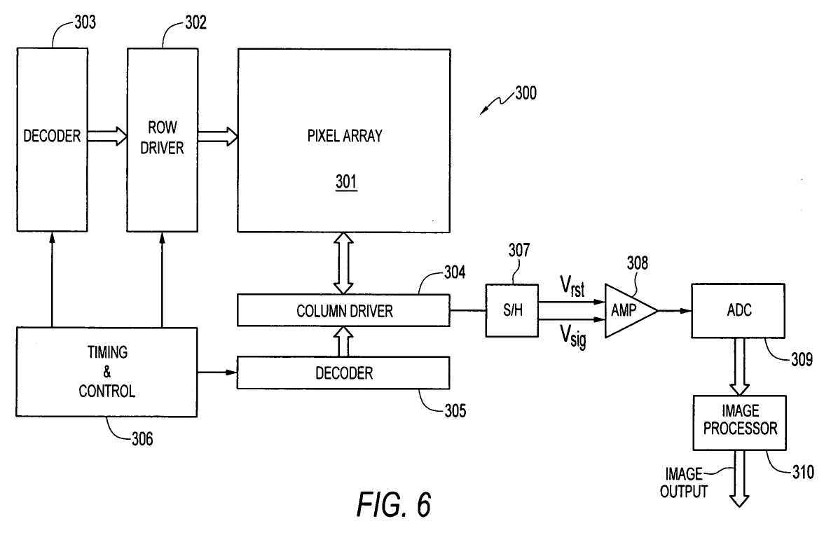

FIG. 6 illustrates a simplified block diagram of an imager 300 employing pixels having at least one microlens as described above. Pixel array 301 comprises a plurality of pixels arranged in a predetermined number of columns and rows. The row lines are selectively activated by the row driver 302 in response to row address decoder 303 and the column select lines are selectively activated by the column driver 304 in response to column address decoder 305. Thus, a row and column address is provided for each pixel cell.

The CMOS imager 300 is operated by a timing and control circuit 306, which controls decoders 303, 305 for selecting the appropriate row and column lines for pixel readout, and row and column driver circuitry 302, 304, which apply driving voltages to the drive transistors of the selected row and column lines. The pixel signals, which typically include a pixel reset signal Vrst and a pixel image signal Vsig for each pixel are sampled by sample and hold circuitry 307 associated with the column driver 304. A differential signal Vrst−Vsig is produced for each pixel, which is amplified by an amplifier 308 and digitized by analog-to-digital converter 309. The analog to digital converter 309 converts the analog pixel signals to digital signals, which are fed to an image processor 310 form a digital image in accordance with the present invention.

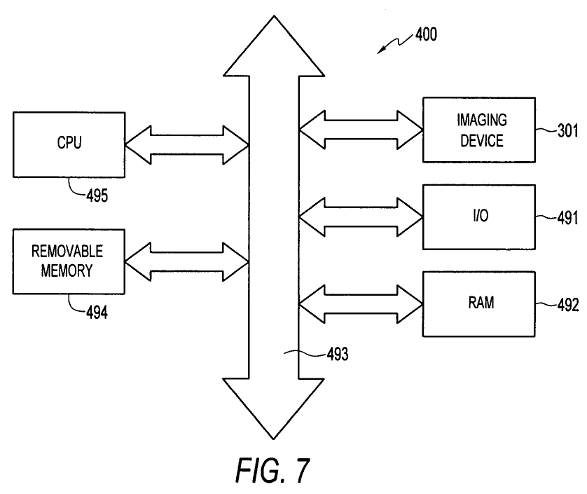

FIG. 7 shows in simplified form a typical processor system 400 modified to include an imaging device 300 (FIG. 6) employing at least one microlens in accordance with the present invention. The processor system 400 is exemplary of a system having digital circuits that could include image sensor devices. Without being limiting, such a system could include a computer system, still or video camera system, scanner, machine vision, vehicle navigation, video phone, surveillance system, auto focus system, star tracker system, motion detection system, image stabilization system, and other systems employing an imaging device.

The processor system 400, for example a digital still or video camera system, generally comprises a central processing unit (CPU) 495, such as a microprocessor which controls camera and one or more image flow functions, that communicates with an input/output (I/O) devices 491 over a bus 493. Imaging device 300 also communicates with the CPU 495 over bus 493. The system 400 also includes random access memory (RAM) 492 and can include removable memory 494, such as flash memory, which also communicate with CPU 495 over the bus 493. Imaging device 300 may be combined with a processor, such as a CPU, digital signal processor, or microprocessor, with or without memory storage on a single integrated circuit or on a different chip than the processor. Although bus 493 is illustrated as a single bus, it may be one or more busses or bridges used to interconnect the system components.

While various embodiments of the present invention have been described above, it should be understood that they have been presented by way of example, and not limitation. For example, although the invention has been described and illustrated in conjunction with pixel structures and a pixel array readout circuit associated with CMOS imagers, it is not so limited and may be employed with any solid state imager pixel structure and associated array readout circuit. It will be apparent to persons skilled in the relevant art(s) that various changes in form and detail can be made therein without departing from the spirit and scope of the present invention. Thus, the present invention should not be limited by any of the above-described exemplary embodiments.

What is claimed as new and desired to be protected by Letters Patent of the United States is:

1. A microlens for use in an imaging device comprising:
at least one pixel comprising a silicon layer having a substantially convex surface located over a photosensitive element of the at least one pixel, said convex surface being configured to direct light to said photosensitive element.

2. The microlens of claim 1, wherein the photosensitive element is integral with a silicon substrate.

3. The microlens of claim 2, wherein the silicon layer is integral with the silicon substrate.

4. The microlens of claim 2, wherein the substantially convex surface of the silicon layer is at a level below the level of a top surface of the silicon substrate.

5. The microlens of claim 4, wherein the substantially convex surface of the silicon layer is defined by a plurality of etched trenches at the top surface of the silicon substrate, wherein the plurality of etched trenches are progressively decreased in depth from the perimeter of the substantially convex surface to a center of the substantially convex surface.

6. The microlens of claim 1, wherein the photosensitive element is at least partially integral with a silicon substrate.

7. The microlens of claim 6, wherein the silicon layer is located over the silicon substrate.

8. The microlens of claim 6, wherein the silicon layer is a polysilicon material located over the silicon substrate.

9. The microlens of claim 8, wherein at least a portion of the photosensitive element is formed in the polysilicon material.

10. The microlens of claim 8, wherein the substantially convex surface of the silicon layer is defined by a plurality of etched trenches at the top surface of the polysilicon material, wherein the plurality of etched trenches are progressively decreased in depth from the perimeter of the substantially convex surface to a center of the substantially convex surface.

11. The microlens of claim 1, further comprising a dielectric layer located over the surface of the substantially convex surface.

12. The microlens of claim 11, wherein the dielectric layer is a nitride anti-reflective coating material.

13. The microlens of claim 11, wherein the dielectric layer is a borophosphosilicate glass material.

14. The microlens of claim 11, wherein a ratio of refraction indices of the silicon layer and the dielectric layer is about 2 to 1.

15. The microlens of claim 14, wherein the index of refraction of the dielectric layer is in the range of approximately 1.47 to approximately 2.0.

16. An imager device comprising:
a pixel array in electrical connection with the processor, wherein the pixel array comprises a plurality of pixels, each pixel comprising:
a photosensor at least partially formed in a silicon substrate; and
a first microlens located over the photosensor, wherein the microlens is formed of a silicon material.

17. The imager device of claim 16, further comprising a borophosphosilicate glass layer over the first microlens.

18. The imager device of claim 17, further comprising a nitride anti-reflective layer between the borophosphsilicate glass layer and the first microlens.

19. The imager device of claim 16, wherein the photosensor is formed entirely in the silicon substrate.

20. The imager device of claim 16, wherein the first microlens has a convex shape and is substantially conformal with the photosensor.

21. The imager device of claim 16, wherein the first microlens is integral with the silicon substrate.

22. The imager device of claim 19, wherein the upper surface of the first microlens is at a level not greater than a level of the top surface of the silicon substrate.

23. The imager device of claim 16, wherein the first microlens is formed of a polysilicon layer over and in contact with the silicon substrate.

24. The imager device of claim 23, wherein the photosensor is at least partially formed in the polysilicon layer.

25. The imager device of claim 17, further comprising a second microlens located over at least the borophosphosilicate glass layer and the first microlens.

26. The imager device of claim 16, further comprising a processor electrically connected to the pixel array.

27. A method of forming a pixel array comprising the steps of:
providing a silicon substrate;
forming a lens by forming a plurality of trenches by:
forming a first plurality of trenches having a first depth in a silicon layer provided over the silicon substrate;
forming at least a second plurality of trenches having a second depth in the silicon layer, wherein the second depth is less than the first depth;
doping the substrate to form a photosensor beneath the surface of the first plurality of trenches; and
providing a dielectric layer over the silicon layer.

28. The method of claim 27, wherein the silicon layer is integral with a top layer of the silicon substrate.

29. The method of claim 27, wherein the first and at least second plurality of trenches are concentric and the second plurality of trenches has a smaller width than the first plurality of trenches.

30. The method of claim 27, wherein the first and at least second plurality of trenches form a substantially convex shape on the top surface of the silicon substrate.

31. The method of claim 27, wherein the silicon layer is integral with the silicon substrate.

32. The method of claim 27, wherein the silicon layer is located over the silicon substrate.

33. The method of claim 27, wherein the first plurality of trenches is below a top surface of the silicon substrate.

34. A method of forming a microlens over a pixel comprising the steps of:
providing a silicon substrate;
forming a plurality of concentric trenches in the silicon substrate, wherein the plurality of trenches form a substantially convex shape on a top surface of the silicon substrate;
doping the substrate to form a photosensor beneath the surface of the plurality of trenches; and
providing a dielectric layer over the silicon layer.

35. The method of claim 34, wherein at least one of the plurality of concentric trenches has a greater diameter and depth than other concentric trenches.

36. The method of claim 34, wherein the plurality of concentric trenches is further formed in a silicon layer over the silicon substrate.

37. The method of claim 34, further comprising at least one top trench that is concentric with the plurality of trenches in the silicon layer, wherein a bottom surface of the top trench is over a top level of the silicon substrate.

38. The method of claim 37, wherein the step of doping the substrate to form a photosensor further comprises doping the silicon layer beneath the surface of the top trench.
